(19) United States
(12) Patent Application Publication
(10) Pub. No.: US 2013/0210256 A1
(43) Pub. Date: Aug. 15, 2013

(54) ELECTRIC CONNECTION BOX

(71) Applicant: DENSO CORPORATION, (US)

(72) Inventor: Toshio Hosokawa, Anjo-city (JP)

(73) Assignee: DENSO CORPORATION, Kariya-city (JP)

(21) Appl. No.: 13/757,895

(22) Filed: Feb. 4, 2013

(30) Foreign Application Priority Data
Feb. 10, 2012 (JP) 2012-26840

(51) Int. Cl. H05K 5/00

(52) U.S. Cl. CPC H05K 5/0091
USPC 439/278

(57) ABSTRACT

An electric connection box includes a circuit board, a box member having a main body part and a cover part, a film-shaped electric wire connected to the circuit board and disposed between the main body part and the cover part, a covering member, and an annular waterproof packing. The box member accommodates the circuit board in an internal space defined by the main body part and the cover part. The covering member covers an outer peripheral surface of a region of the wire between the main body part and the cover part along its whole circumference. The box member includes a fitting part fitted to the covering member. The packing is disposed around the circuit board and compressed between the main body part and the cover part. The packing includes an annular part pressing an outer peripheral surface of the covering member along the box member over its entire circumference.

### CROSS REFERENCE TO RELATED APPLICATION

This application is based on Japanese Patent Application No. 2012-26840 filed on Feb. 10, 2012, the disclosure of which is incorporated herein by reference.

### TECHNICAL FIELD

The present disclosure relates to an electric connection box that is connected to a circuit board and a film-shaped electric wire.

### BACKGROUND

The electric connection box is used for various purposes, and its various waterproof structures have been researched. A structure of an electric connection box connected to a wire harness and a circuit board is described in, for example, JP-A-2001-251724. In such an electric connection box, a connecting portion (connector) for introducing the wire harness into a box member is provided at a part located between a lower part and an upper part of the box member.

However, in the above-described electric connection box, the connecting portion needs to be provided separately from the wire harness and a packing. It is difficult to achieve reduction of the number of components and improvement in attachment workability with waterproofness of the connecting portion secured.

### SUMMARY

The present disclosure addresses at least one of the above issues.

According to the present disclosure, there is provided an electric connection box including a circuit board, a box member, a film-shaped electric wire, a covering member, and an annular waterproof packing. The box member includes a main body part and a cover part. The circuit board is disposed in the main body part. The cover part covers the main body part. The box member accommodates the circuit board in an internal space defined by the main body part and the cover part. The film-shaped electric wire is connected to the circuit board and is disposed between the main body part and the cover part. The covering member covers an outer peripheral surface of a region of the film-shaped electric wire between the main body part and the cover part, along its whole circumference. The box member further includes a fitting part that is fitted to the covering member. The waterproof packing is disposed around the circuit board and is compressed between the main body part and the cover part. The waterproof packing includes an annular part that presses an outer peripheral surface of the covering member along the box member, over an entire circumference thereof.

As a result of this configuration, high waterproofness is achieved by the waterproof packing having two regions whose compression directions are different. Moreover, according to the present disclosure, a simple structure in which the film-shaped electric wire and the circuit wiring are connected together without through a connecting member such as a connector, and the covering member is fitted to the box member, is provided. Furthermore, the waterproof packing is configured as one component, part of which is the annular part. Therefore, according to the present disclosure, the number of components can be reduced, improvement in attachment workability by the simple structure, and cost reduction are made possible.

According to the present disclosure, there is also provided an electric connection box including a circuit board, a box member, a film-shaped electric wire, and an annular waterproof packing. The box member includes a main body part and a cover part. The circuit board is disposed in the main body part. The cover part covers the main body part. The box member accommodates the circuit board in an internal space defined by the main body part and the cover part. The film-shaped electric wire is connected to the circuit board and is disposed between the main body part and the cover part. The waterproof packing is disposed around the circuit board and is clamped between the main body part and the cover part to be arranged in a compressed state. The film-shaped electric wire is insert-molded in the waterproof packing. The waterproof packing includes an annular part that presses an outer peripheral surface of the film-shaped electric wire along the box member, over an entire circumference thereof.

As a result of this configuration, similar effects to the above are produced.

### BRIEF DESCRIPTION OF THE DRAWINGS

The above and other objects, features and advantages of the present disclosure will become more apparent from the following detailed description made with reference to the accompanying drawings. In the drawings:

FIG. 1 is an exploded perspective view illustrating a configuration of an electric connection box in accordance with a first embodiment;

FIG. 2 is a plan view illustrating the electric connection box of the first embodiment;

FIG. 3 is a sectional view taken along a line in FIG. 2;

FIG. 4 is a partially enlarged view illustrating a covering member in FIG. 3;

FIG. 5 is a plan view illustrating an inner part of the electric connection box of the first embodiment;

FIG. 6 is a cross-sectional view taken along a line VI-VI in FIG. 3 illustrating a waterproof packing;

FIG. 7 is a diagram illustrating an exemplary arrangement of the electric connection box of the first embodiment; and

FIG. 8 is a cross-sectional view illustrating a waterproof packing in accordance with a second embodiment, which corresponds to FIG. 6.

### DETAILED DESCRIPTION

An electric connection box of the present disclosure will be described in detail with the following embodiments. An application of the electric connection box of the present disclosure to an occupant detection sensor arranged in a vehicle seat will be illustrated below. The drawings are conceptual diagrams, and do not necessarily indicate accurate sizes.

### First Embodiment

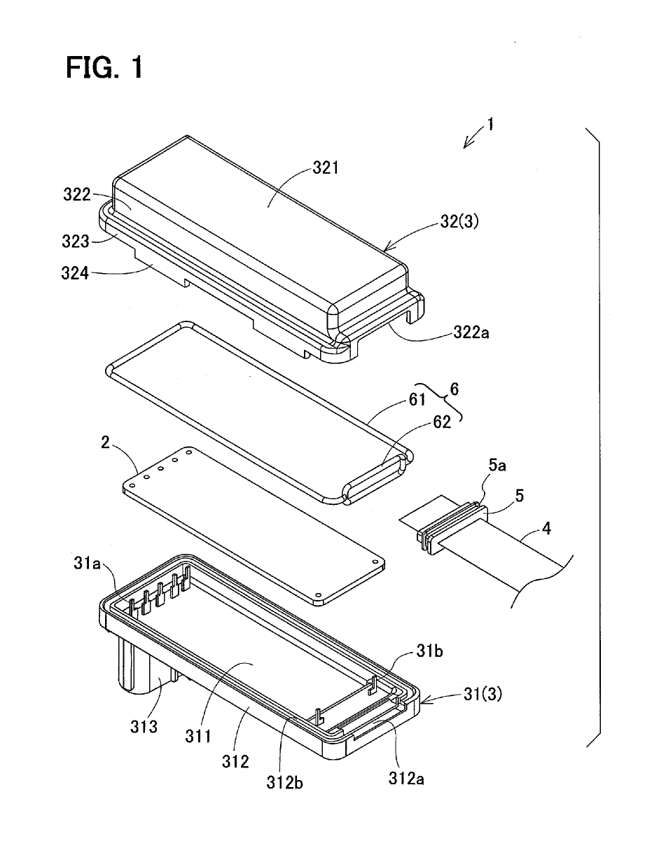

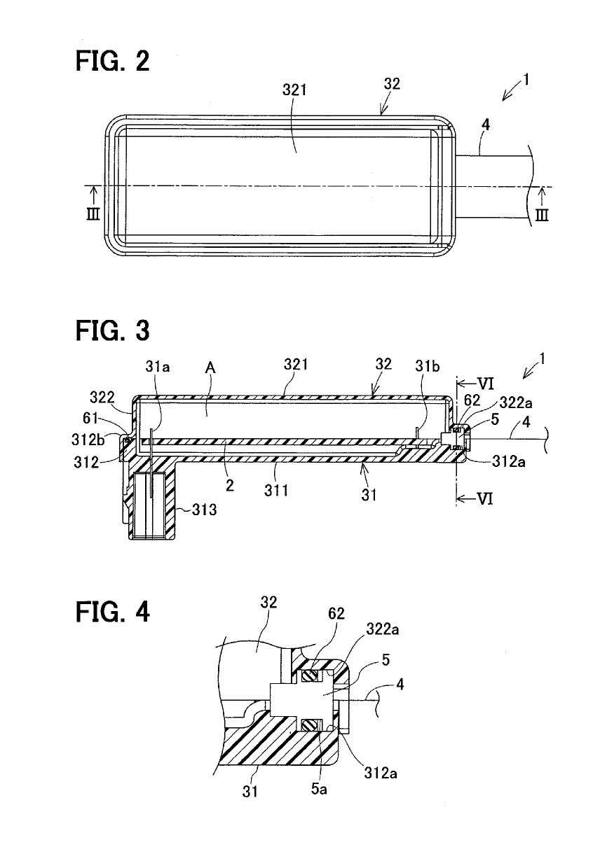

As illustrated in FIGS. 1 to 6, an electric connection box 1 of a first embodiment includes a circuit board 2, a box member 3, a film-shaped electric wire 4, a covering member 5, and a waterproof packing 6. The circuit board 2 is a plate-shaped printed circuit board. The circuit board 2 is connected to terminals 31a, 31b of a main body part 31 (discussed below). The circuit board 2 is connected to the film-shaped electric wire 4 (discussed below). In the following description, side of the circuit board 2 to which the film-shaped electric wire 4 is connected is referred to as a wiring side (right side in FIG. 2), and an opposite side of the board 2 from this wiring side is referred to as a counter-wiring side (left side in FIG. 2). In addition, in the description, explanation will be given with a perpendicular direction to a flat surface of the circuit board 2 referred to as upper and lower directions, its one side being an upper side and the other side being a lower side. The circuit board 2 of the present embodiment is an occupant detection electronic control unit (ECU).

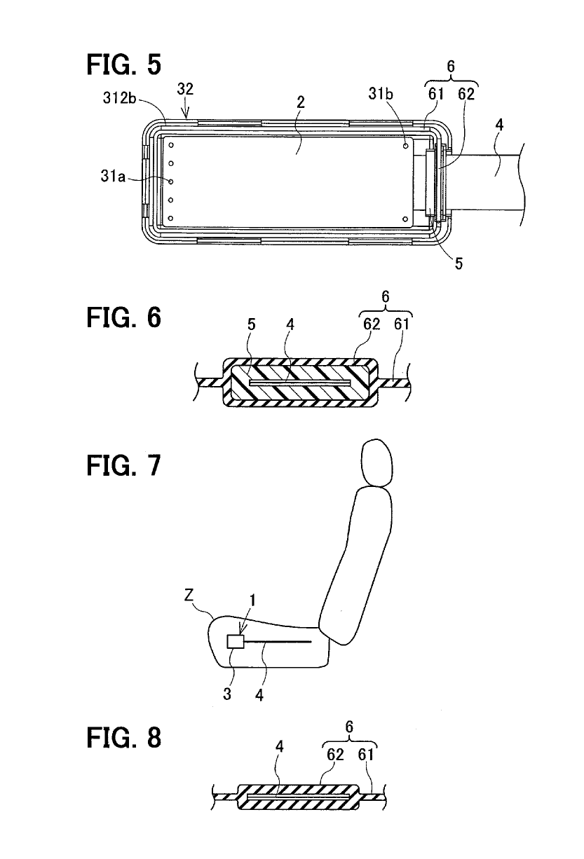

The box member 3 is made from resin, and includes the main body part 31 and a cover part 32. The main body part 31 is formed in a cylindrical shape having a bottom with its upper part opening. Specifically, the main body part 31 includes a plate-shaped bottom wall 311, an edge portion 312 that projects upward from the whole circumference of an edge of the bottom wall 311, and a connector portion 313 that projects downward from an end of the bottom wall 311 on its counter-wiring side. As illustrated in FIGS. 3 and 5, the circuit board 2 is arranged on an inner side of the main body part 31 that is surrounded with the edge portion 312. In other words, the edge portion 312 of the main body part 31 projects from the bottom wall 311 to surround the circuit board 2.

The edge portion 312 includes a recessed fitting part 312a into which the covering member 5 is fitted on the wiring side, and a rail part 312b which is recessed continuously along the whole circumference of an upper end of the portion 312 except the fitting part 312a. The connector portion 313 is formed into a cylindrical shape having a bottom that opens downward, and is for connecting together a connector (not shown) such as an external device and the circuit board 2. The circuit board 2 communicates with another device (e.g., air bag ECU) via the connector portion 313.

The main body part 31 includes terminals 31a projecting in the upper and lower directions from the counter-wiring side end of the bottom wall 311 inward of the edge portion 312, and terminals 31b projecting upward from the wiring side end of the bottom wall 311. The terminals 31a, 31b pass through the circuit board 2 to be electrically connected to the circuit board 2 and to fix the circuit board 2 to the main body part 31. The lower end of the terminal 31a is exposed to the inside of the connector portion 313. The terminals 31a, 31b and the circuit board 2 may be soldered together.

The cover part 32 is formed in a cylindrical shape having a bottom that opens downward. The cover part 32 closes an opening of the main body part 31. The cover part 32 includes a plate-shaped bottom wall 321 and an edge portion 322. The edge portion 322 projects downward from the whole circumference of an edge of the bottom wall 321. An end of the edge portion 322 on its wiring side is provided with a recessed fitting part 322a, into which the covering member 5 is fitted. A lower end portion of the edge portion 322 of the cover part 32, and an upper end portion of the edge portion 312 of the main body part 31 are in contact with each other.

A covering part 323 that covers an upper portion of an outer periphery of the edge portion 312 of the main body part 31, and a fitting part 324 that is fitted to the main body part 31 in the upper and lower directions are further provided for an outer circumference of the edge portion 322. The cover part 32 and the main body part 31 are in engagement with each other in a direction of the flat surface of the circuit board 2 through the covering part 323. As above, the cover part 32 and the main body part 31 are fixed together by the covering part 323 and the fitting part 324. The box member 3 accommodates the circuit board 2 in an internal space A which is defined by the main body part 31 and the cover part 32. In the present embodiment, the box member 3 is arranged in the vehicle seat.

The film-shaped electric wire 4 is a flexible electric wire having a film shape (e.g., membrane and flexible printed circuit (FPC)), and is configured mainly by disposing a conductive foil (electric wire) on a film-shaped insulating material. Thickness (width in the upper and lower directions) of the film-shaped electric wire 4 is expressed in a unit of micrometer. A connecting terminal (not shown) which is, for example, soldered to the circuit board 2 is provided for an end portion (counter-wiring side end portion) of the film-shaped electric wire 4. The film-shaped electric wire 4 of the present embodiment functions as a sensor part arranged in the vehicle seat to detect an occupant.

The covering member 5 is formed to cover the whole circumference of an outer peripheral surface of a part of the film-shaped electric wire 4 by hot-melt resin. The covering member 5 is provided at a region of the film-shaped electric wire 4 located between the main body part 31 and the cover part 32. A rail groove 5a is formed on an outer peripheral surface of the covering member 5 along the box member 3 along the whole circumference. In other words, the rail groove 5a is formed along the fitting parts 312a, 322a. The waterproof packing 6 is disposed in the rail groove 5a.

The covering member 5 is clamped between the main body part 31 and the cover part 32 in the upper and lower directions, and is fitted to the fitting part 312a of the main body part 31 and the fitting part 322a of the cover part 32. Accordingly, the covering member 5 is engaged with and fixed to the box member 3 in the upper and lower directions as well as in the direction of the flat surface of the circuit board 2. The covering member 5 is formed from hot melt (resin). Therefore, deformation of the member 5 is limited against stress in a direction (hereinafter referred to as a tension direction) from an end of the circuit board 2 on the opposite side from the wire 4 toward an end of the board 2 on the side of the wire 4 among the direction of the flat surface of the circuit board 2, and the member 5 thereby provides excellent fixing force. The covering member 5 is formed by melting and solidifying hot melt resin. Thickness (width in the upper and lower directions) of the covering member 5 is expressed in a unit of millimeter (e.g., 2 mm or longer).

The waterproof packing 6 is a sealing member made of rubber, and is a packing formed in an annular shape as a whole. The waterproof packing 6 is disposed in a state where the packing 6 is clamped between the main body part 31 and the cover part 32 to be compressed by the main body part 31 and the cover part 32.

As illustrated in FIGS. 1 and 6, an annular part 62 that presses an outer peripheral surface of the covering member 5 along its whole circumference is provided for a part of the waterproof packing 6. In other words, the waterproof packing 6 includes a packing main body part 61 in a generally annular shape, part of which is cut to be open, and the annular part 62 located at the cut part of the packing main body part 61. The packing main body part 61 is formed into a generally annular shape, part of which opens in a C-shaped, U-shaped, or angulated U-shaped manner. The packing main body part 61 is disposed in the rail part 312b of the main body part 31, and is clamped between the rail part 312b and the edge portion 322 of the cover part 32 to be pressed in the upper and lower directions.

The annular part 62 is formed into an annular shape and integrally connects together generally annular both ends (separated ends) of the packing main body part 61. An axial direction of the annular shape of the annular part 62 (right and left directions in FIG. 3) intersects (perpendicularly in the present embodiment) with an axial direction of the generally annular shape of the packing main body part 61 (upper and lower directions in FIG. 3). As illustrated in FIG. 4, an inner peripheral side of the annular part 62 is in contact with the rail groove 5a of the covering member 5. The annular part 62 presses the rail groove 5a of the covering member 5 along its whole circumference.

An outer peripheral side of the annular part 62 is in contact with the wiring side ends of the main body part 31 and the cover part 32. Specifically, an outer peripheral lower side of the annular part 62 is disposed at the fitting part 312a of the main body part 31, and an outer peripheral upper side of the annular part 62 is disposed at the fitting part 322a of the cover part 32. The annular part 62 is clamped and compressed between the fitting part 312a and the rail groove 5a as well as between the fitting part 322a and the rail groove 5a. The fitting parts 312a, 322a respectively press the outer periphery of the annular part 62 toward the rail groove 5a. Thus, the annular part 62 is compressed in a circumferential direction of the covering member 5. Thickness of the annular part 62 is ensured because of the covering member 5. Accordingly, the annular part 62 can be easily and without any space closely-attached to the whole circumference of the covering member 5.

The waterproof packing 6 is formed as one component with the packing main body part 61 and the annular part 62 integrally formed. The covering member 5 is fitted into the opening of the end of the box member 3 on the wiring side (see FIG. 1) that is defined by the fitting parts 312a, 322a. A size (width in the right and left directions and thickness in the upper and lower directions) of this opening is smaller than a size of outer diameter (see FIG. 6) of the annular part 62 that is disposed around the outer periphery of the covering member 5.

As above, the waterproof packing 6 includes the packing main body part 61 whose compression direction is the upper-lower direction (thickness direction), and the annular part 62 whose compression direction is the circumferential direction of the covering member 5. Therefore, the waterproof packing 6 includes the regions whose compression directions are different with the packing 6 clamped by the box member 3. The waterproof packing 6 is disposed around the circuit board 2 to surround the circuit board 2. In other words, the waterproof packing 6 is disposed along a joining part (edge portions 312, 322) between the main body part 31 and the cover part 32 to seal the inside of the box member 3. The arrangement position of the waterproof packing 6 in the upper and lower directions may be different from the arrangement position of the circuit board 2 in the upper and lower directions.

According to the electric connection box 1 of the present embodiment, the waterproof packing 6 having two regions whose compression directions are different seals clearances between the main body part 31 and the cover parts 32; between the main body part 31 and the covering member 5; and between the cover part 32 and the covering member 5. As a result, high waterproofness of the box 1 is produced. Furthermore, the box 1 has a simple structure for connecting together the circuit board 2 and the film-shaped electric wire 4 without a connector (directly), and the waterproof packing 6 is formed as one component. Accordingly, the number of components can be reduced, and the improvement in attachment workability and cost reduction are made possible.

In the present embodiment, the covering member 5, which is fitted to the box member 3, is formed from hot melt. Accordingly, even when the film-shaped electric wire 4 is stretched in the tension direction, the covering member 5 is not easily deformed to maintain its shape. As a result, when the film-shaped electric wire 4 is pulled, application of a load to the connecting portion between the circuit board 2 and the film-shaped electric wire 4 is limited. Even if the covering member 5 is formed from a member other than the hot melt (e.g., rubber member such as grommet), a certain level of tensile strength and a waterproof structure equivalent to the above can be ensured.

Particularly, as illustrated in FIG. 7, when the electric connection box 1 is disposed in a vehicle seat Z as an occupant detection sensor, a load can be applied to the film-shaped electric wire 4 in the tension direction due to the occupant seating. Even in such a case, in the electric connection box 1 of the present embodiment, the load application to the connecting part between the circuit board 2 and the film-shaped electric wire 4 is limited against the tension. Thus, when the covering member 5 is the hot melt, additional benefits can be provided.

In the above-described case, for example, the circuit board 2 may be the occupant detection ECU as above, and the film-shaped electric wire 4 may function as an electrode (sensor part) for measuring electrostatic capacity between a vehicle body and the seat Z. In this case, the electric connection box 1 detects an occupant as a result of a change of electrostatic capacity between the body and the seat Z due to the occupant seating. In addition, the film-shaped electric wire 4 may be a load sensor which detects a load. Therefore, when the electric connection box 1 is used as an occupant detection sensor, those functioning as a sensor for detecting the occupant seating can be employed for the film-shaped electric wire 4.

### Second Embodiment

An electric connection box 1 of a second embodiment employs a structure with the covering member 5 eliminated in the first embodiment. In the electric connection box 1 of the second embodiment, as illustrated in FIG. 8, an annular part 62 of a waterproof packing 6 is in contact with the entire outer periphery of a region of a film-shaped electric wire 4 that is clamped by a box member 3. A recessed part (not shown) that is depressed and thinner than the fitting parts 312a, 322a of the first embodiment is formed at a wiring side end of the box member 3 of the second embodiment. The annular part 62 is clamped between this recessed part and the film-shaped electric wire 4 to be in a state compressed in the circumferential direction. Similar to the first embodiment, a clearance is not formed between this recessed part and the annular part 62.

The above-described structure of the second embodiment is formed through insert-molding of the film-shaped electric wire 4 in the waterproof packing 6. By the insert-molding, the annular part 62 that is closely-attached to the entire outer periphery of the film-shaped electric wire 4 can be easily formed. Accordingly, as for the thin film-shaped electric wire 4 as well, a clearance is not formed between the film-shaped electric wire 4 and the annular part 62. Thus, waterproofness of the box 1 is ensured.

In the second embodiment, security of waterproof, improvement in attachment, and a further cost reduction effect, which are similar to the first embodiment, are produced. Fixing force of the film-shaped electric wire 4 against the tension is more excellent in the first embodiment because of the existence of the covering member 5.

In the first embodiment and the second embodiment, either one of the edge portion 312 of the main body part 31 and the edge portion 322 of the cover part 32 does not need to project relative to the bottom walls 311, 321. For example, the main body part 31 or the cover part 32 may have a shape of a flat plate as a whole.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. An electric connection box comprising:
a circuit board;
a box member that includes:
a main body part in which the circuit board is disposed; and
a cover part covering the main body part, wherein the box member accommodates the circuit board in an internal space defined by the main body part and the cover part;
a film-shaped electric wire that is connected to the circuit board and is disposed between the main body part and the cover part;
a covering member that covers an outer peripheral surface of a region of the film-shaped electric wire between the main body part and the cover part, along its whole circumference, wherein the box member further includes a fitting part that is fitted to the covering member; and
an annular waterproof packing that is disposed around the circuit board and is compressed between the main body part and the cover part, wherein the waterproof packing includes an annular part that presses an outer peripheral surface of the covering member along the box member, over an entire circumference thereof.

2. The electric connection box according to claim 1, wherein the covering member is hot melt.

3. The electric connection box according to claim 1, wherein:
the box member is disposed in a seat of a vehicle; and
the film-shaped electric wire is a sensor that is arranged in the seat for detecting an occupant of the vehicle.

4. An electric connection box comprising:
a circuit board;
a box member that includes:
a main body part in which the circuit board is disposed; and
a cover part covering the main body part, wherein the box member accommodates the circuit board in an internal space defined by the main body part and the cover part;
a film-shaped electric wire that is connected to the circuit board and is disposed between the main body part and the cover part; and
an annular waterproof packing that is disposed around the circuit board and is clamped between the main body part and the cover part to be arranged in a compressed state, wherein:
the film-shaped electric wire is insert-molded in the waterproof packing; and
the waterproof packing includes an annular part that presses an outer peripheral surface of the film-shaped electric wire along the box member, over an entire circumference thereof.

5. The electric connection box according to claim 4, wherein:
the box member is disposed in a seat of a vehicle; and
the film-shaped electric wire is a sensor that is arranged in the seat for detecting an occupant of the vehicle.
